(19) United States
(12) Patent Application Publication
(10) Pub. No.: US 2021/0069745 A1
(43) Pub. Date: Mar. 11, 2021

(54) VAPOR DELIVERY METHODS AND APPARATUS

(71) Applicant: Applied Materials, Inc., Santa Clara, CA (US)

(72) Inventors: Alexander N. LERNER, San Jose, CA (US); Roey SHAVIV, Palo Alto, CA (US); Phillip STOUT, Santa Clara, CA (US); Prashanth KOTHNUR, San Jose, CA (US); Joseph M. RANISH, San Jose, CA (US)

(21) Appl. No.: 17/013,462

(22) Filed: Sep. 4, 2020

Related U.S. Application Data
(60) Provisional application No. 62/898,098, filed on Sep. 10, 2019.

(51) Int. Cl. B05D 1/00; B05B 1/00; B05B 15/60; B05B 1/18; B05B 11/00; B05B 12/14; B05B 1/16

(52) U.S. Cl. CPC B05D 1/60; B05B 1/005; B05B 15/60; B05B 1/1681; B05B 11/0008; B05B 12/14; B05B 1/185

(57) ABSTRACT

Embodiments of the present disclosure generally relate to organic vapor deposition systems and substrate processing methods related thereto. In one embodiment, a processing system comprises a lid assembly and a plurality of material delivery systems. The lid assembly includes lid plate having a first surface and a second surface disposed opposite of the first surface and a showerhead assembly coupled to the first surface. The showerhead assembly comprises a plurality of showerheads. Individual ones of the plurality of material delivery systems are fluidly coupled to one or more of the plurality of showerheads and are disposed on the second surface of the lid plate. Each of the material delivery systems comprise a delivery line, a delivery line valve disposed on the delivery line, a bypass line fluidly coupled to the delivery line at a point disposed between the delivery line valve and the showerhead, and a bypass valve disposed on the bypass line.

### CROSS-REFERENCE TO RELATED APPLICATIONS

This application claims priority to U.S. Provisional Application 62/898,098, filed on Sep. 10, 2019, which is herein incorporated by reference in its entirety.

### BACKGROUND

### Field

Embodiments described herein generally relate to electronic device manufacturing, and more particularly, to organic vapor deposition systems and substrate processing methods related thereto.

### Description of the Related Art

Organic vapor deposition is becoming increasingly relevant in the manufacturing of integrated organic photoelectric devices, such as complementary metal-oxide semiconductor (CMOS) image sensors. A CMOS image sensor (CIS) typically features a plurality of organic photo-detectors (OPDs) integrally formed with a corresponding plurality of CMOS transistors. Each OPD-CMOS transistor combination provides a pixel signal which, when combined with other pixel signals provided by the image sensor, can be used to form an image. Typically, the OPDs are formed from a patterned film stack comprising one or more layers of organic photo-conductive films interposed between two transparent electrode layers, such as indium-tin-oxide (ITO) electrode layers. The CMOS devices are typically formed on a silicon substrate, e.g., a wafer, using a conventional semiconductor device manufacturing process, and the organic photo-detectors are then formed there over. The organic photo-conductive films are typically deposited onto a masked substrate having a plurality of CMOS devices formed thereon using an organic vapor deposition process.

Organic vapor deposition processes are commonly used in the manufacturing of organic light emitting diode (OLED) displays, such as television screens, or large scale arrays of organic photo-detectors, such as solar cells, where the organic devices are formed on a large rectangular panel. Unfortunately, integrating organic vapor deposition processes conventionally used in panel manufacturing into high-volume semiconductor device manufacturing lines has proven challenging.

Accordingly, what is needed in the art are organic vapor deposition systems suitable for handling substrates which are commonly used for semiconductor device manufacturing and substrate processing methods related thereto.

### SUMMARY

Embodiments of the present disclosure generally relate to organic vapor deposition systems suitable for the manufacturing of integrated organic CMOS image sensors and methods related thereto.

In one embodiment a processing system comprises a lid assembly and a plurality of material delivery systems. The lid assembly comprises a lid plate having a first surface and a second surface disposed opposite of the first surface and a showerhead assembly coupled to the first surface. The showerhead assembly comprises a plurality of showerheads. Here, individual ones of the plurality of material delivery systems are disposed on the second surface of the lid plate and are fluidly coupled to one or more of the plurality of showerheads. Typically, the individual ones of the material delivery systems each comprise a delivery line, a delivery line valve disposed on the delivery line, a bypass line fluidly coupled to the delivery line at a point disposed between the delivery line valve and the showerhead, and a bypass valve disposed on the bypass line.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 schematically illustrates an organic vapor deposition processing system featuring a processing chamber shown in cross section and a plurality of material delivery systems fluidly coupled to the processing chamber, according to one embodiment.

FIG. 2A is a schematic bottom up view of a lid assembly which may be used as the lid assembly of the processing chamber shown in FIG. 1, according to one embodiment.

FIG. 2B is a right-side-up schematic sectional view of the lid assembly of FIG. 2A taken along line A-A which further illustrates a plurality of integrated material delivery systems disposed on a lid plate of the lid assembly, according to one embodiment.

FIG. 2C is a close up sectional view of one of the vapor sources described in FIG. 2B, according to one embodiment.

FIG. 2D is a close up sectional view of a portion of FIG. 2B, according to one embodiment.

FIG. 3 is a sectional view of a vapor source, according to another embodiment, which may be used in place of one or more of the vapor sources described in FIG. 1 or 2B.

FIGS. 4A-4B are close up sectional views of alternative embodiments to the bellows illustrated in FIGS. 2B and 2D.

FIG. 5 is a flow diagram setting forth a method of processing a substrate using the processing systems described herein, according to one embodiment.

To facilitate understanding, identical reference numerals have been used, where possible, to designate identical elements that are common to the figures. It is contemplated that elements and features of one aspect may be beneficially incorporated in other aspects without further recitation.

### DETAILED DESCRIPTION

Embodiments of the present disclosure generally relate to organic vapor deposition systems suitable for the manufacturing of integrated organic CMOS image sensors and substrate processing methods related thereto.

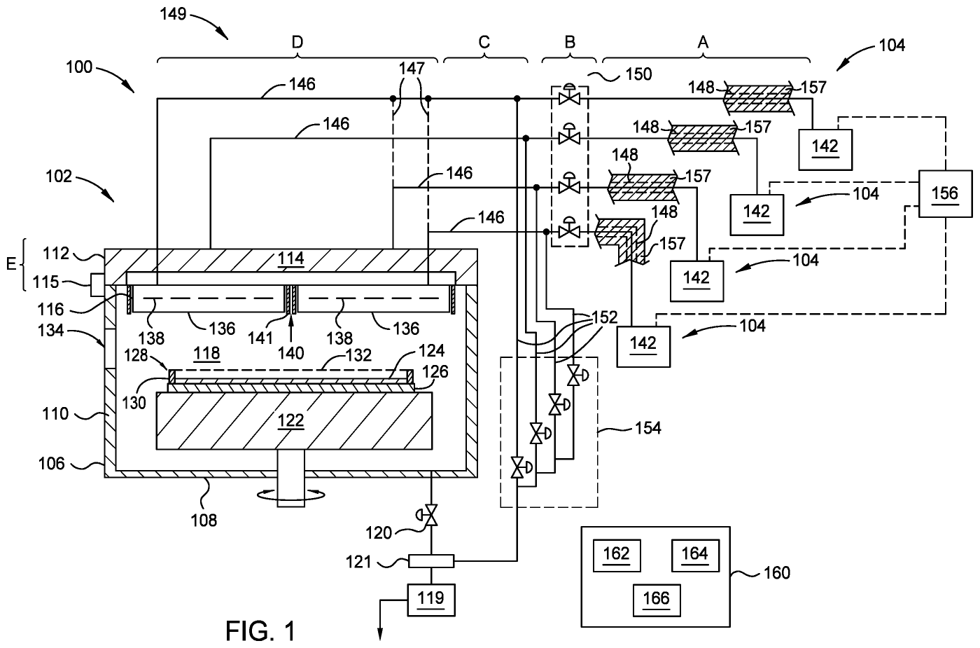

FIG. 1 schematically illustrates a processing system 100 which may be used to deposit one or more organic materials onto the surface of a substrate, according to one embodiment. The processing system 100 features a processing chamber 102 (shown in cross section) and a plurality of material delivery systems 104 fluidly coupled thereto. The term “fluidly coupled” as used herein refers to two or more elements that are directly or indirectly connected such that the two or more elements are in fluid communication, i.e., such that fluid may directly or indirectly flow therebetween.

The processing chamber 102 includes a chamber body 106 which comprises a chamber base 108, one or more sidewalls 110, and a chamber lid assembly 112. The chamber lid assembly 112 includes a lid plate 114 and a showerhead assembly 116 coupled to the lid plate 114. Here, the lid plate 114 is coupled to the one or more sidewalls 110 using a hinge 115, which allows the lid plate 114 to pivot, swing, or otherwise move away from the sidewalls 110 to allow access for maintenance. In other embodiments, the lid plate 114 may be moved away from the sidewalls 110 using a crane disposed above lid plate 114 which lifts the lid plate 114. Here, the chamber base 108, the one or more sidewalls 110, and the showerhead assembly 116 collectively define a processing volume 118.

Typically, the processing volume 118 is fluidly coupled to a vacuum source 119, such as to one or more dedicated vacuum pumps, which maintains the processing volume 118 at sub-atmospheric conditions and evacuates excess vapor-phase organic materials therefrom. Here, a valve 120, e.g., a throttle valve, is disposed on an exhaust line between the processing volume 118 and the vacuum source 119. The valve 120 is used to control the pressure in the processing volume 118. In some embodiments, the processing system 100 further includes a cold trap 121 disposed between the processing volume 118 and the vacuum source 119. The cold trap 121 may be thermally coupled to a coolant source (not shown) and is used to condense and trap excess vapor-phase organic material before the vapor-phase organic material reaches the one or more dedicated vacuum pumps and undesirably condenses on the surfaces therein.

Herein, the processing chamber 102 further includes a rotatable substrate support 122 disposed in the processing volume 118 to support and rotate a substrate 124 during the vapor deposition process. In some embodiments, the substrate 124 is disposed on a substrate carrier 126, such as a portable electrostatic chuck, which further supports a shadow mask assembly 128. The shadow mask assembly 128 includes a mask frame 130 and a shadow mask 132 disposed within, and supported by, the mask frame 130 to span a surface of the substrate 124. During substrate processing, organic materials are deposited (condensed) onto the substrate 124 through openings in the shadow mask 132 disposed thereabove. Organic materials deposited onto the substrate 124 through the openings in the shadow mask 132 form one or more patterned organic material layers on the substrate surface. The substrate carrier 126, having the substrate 124 and the shadow mask assembly 128 disposed thereon, is loaded and unloaded to and from substrate support 122 through an opening 134 in one of the sidewalls 110 which is sealed by a door or a valve (not shown).

The showerhead assembly 116 includes a plurality of showerheads 136 (two of four showerheads are shown) each of which may be used to distribute a vapor-phase organic material into the processing volume 118. Each of the showerheads 136 features a heater 138 which may be used to independently control the temperature of the respective showerhead 136 relative to each of the other showerheads 136 of the showerhead assembly 116. As discussed further below, controlling the temperature of the components of the material delivery systems 104 and the showerheads 136 facilitates control over the mass flow rate of the vapor-phase organic material into the processing volume 118. For example, when the temperature of a component and/or a showerhead 136 is increased, the flow of vapor-phase organic material therethrough also increases. Thus, the ability to independently control the temperature of each of the showerheads 136 relative to one another advantageously facilitates independent control over the flow rates of the respective organic materials therethrough. Here, each of the showerheads 136 are spaced apart from an adjacently disposed showerhead 136 by a gap 140 to reduce or substantially eliminate thermal cross-talk therebetween.

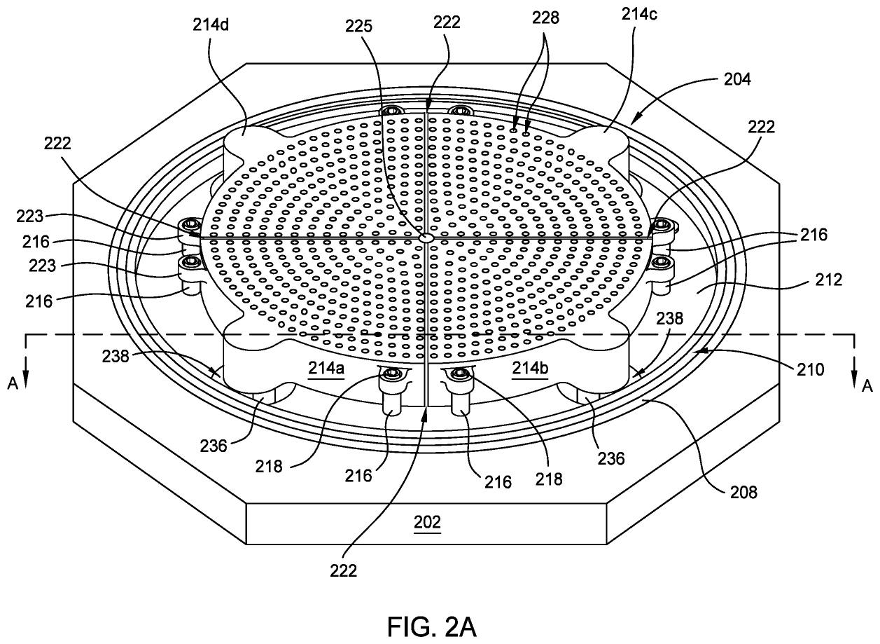

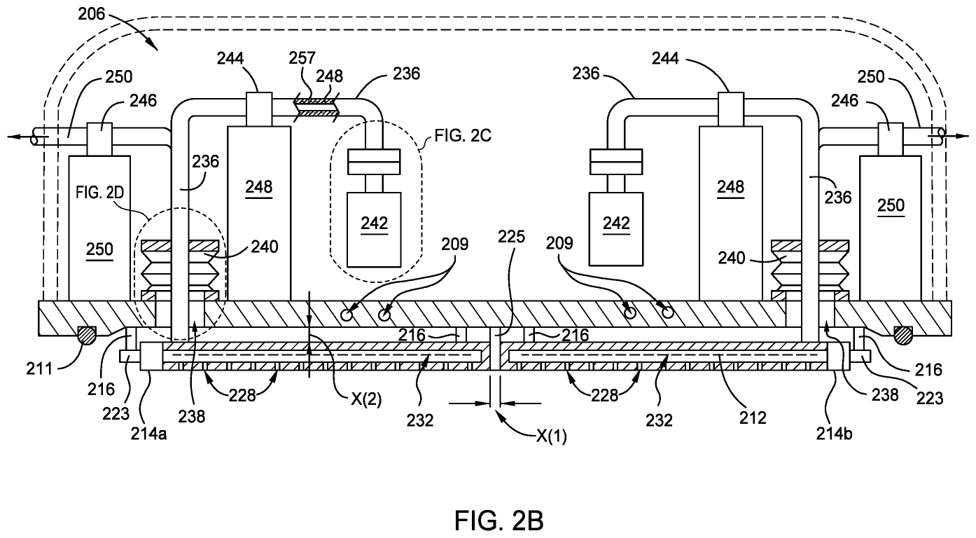

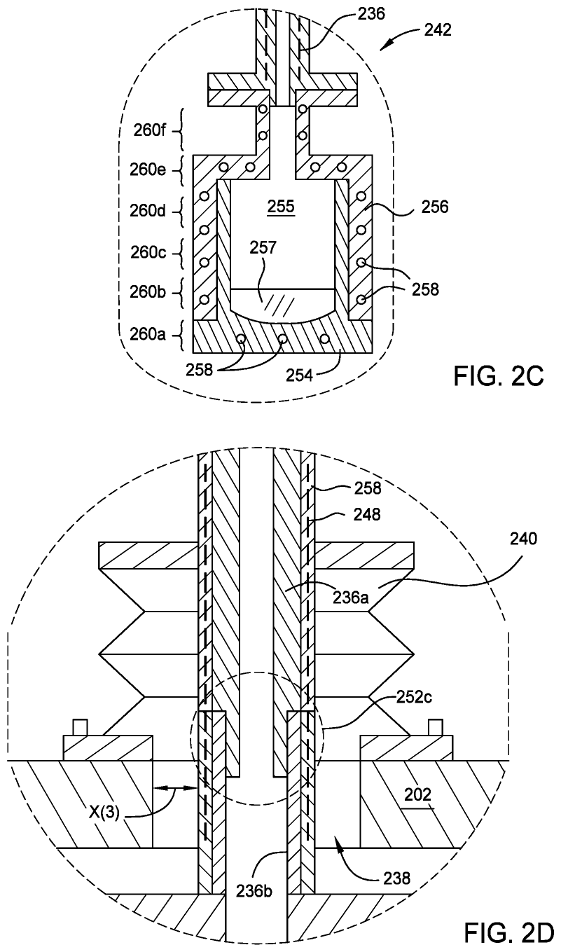

In some embodiments, each of the showerheads 136 are surrounded by a reflector 141. Typically, each of the reflectors 141 comprise a metal having a highly polished surface, e.g., a mirrored surface, which faces the showerhead. The reflectors 141 are used to arrest heat within the respective showerhead 136, e.g., to prevent radiant heat loss from the sides of the showerhead 136 into the processing volume 118 and to prevent thermal cross-talk between adjacent showerheads 136. Further aspects of a showerhead assembly which may be used with the processing chamber 102 in place of the showerhead assembly 116 are shown and described in FIGS. 2A-2B.

Here, vapor-phase organic materials are delivered to each of the showerheads 136 using the plurality of material delivery systems 104 (four shown). Each of the material delivery systems 104 includes a vapor source 142 and a delivery line 146 fluidly coupling the vapor source 142 to a showerhead 136. In some embodiments, the delivery lines 146 fluidly couple each of the vapor sources 142 to a respective showerhead 136 in a one-to-one relationship where each of the showerheads 136 has an individual vapor source 142 corresponding thereto. In other embodiments, two or more showerheads 136 may be fluidly coupled to an individual vapor source 142, such as by using a second delivery line 147 (shown in phantom) which is fluidly coupled to a first delivery line 146.

During operation of the processing system 100, the vapor sources 142 will typically contain a solid-phase organic material, such as an organic powder, which is heated under vacuum to vaporize or sublimate the organic material into a vapor-phase thereof. Here, the delivery lines 146 are heated using respective heaters 148, such as resistive heating elements, which are thermally coupled thereto. The heaters 148 may extend along the lengths of the delivery lines 146 from the vapor sources 142 to the showerheads 136 or may extend along portions of the lengths of the delivery lines 146, such as from the vapor sources 142 to the lid plate 114. The heaters 148 prevent undesirable condensation of the vapor-phase organic materials in the delivery lines 146 and, in some embodiments, may be used to control the flow rates of vapor-phase organic materials through the delivery lines 146.

In some embodiments, one or more of the material delivery systems 104 feature a plurality of independently controlled heaters 148 each extending along a portion of the material delivery system 104 from the respective vapor source 142 to the corresponding showerhead 136. The plurality of independently controlled heaters 148 are used to form a multi-zone control heating system 149, e.g., zones A-E, from the respective vapor source 142 to the corresponding showerhead 136. In some embodiments, the multi-zone control heating system 149 is used to maintain uniform temperatures along the length of individual material delivery systems 104, e.g., from the respective vapor source 142 to and including the corresponding showerhead 136. In some embodiments, the multi-zone control heating system 149 is used to gradually and/or progressively change (increase or decrease) the temperatures of the individual material delivery systems 104 along the length thereof to provide fine control over the material flowrates of the vapor-phase precursors disposed therein.

Herein, at least portions of the material delivery systems 104, such as the delivery lines 146, delivery line valves 150, connections, and the heaters 148 thermally coupled thereto are disposed within a thermally insulating material, such as an insulating jacket 157. The insulating jacket 157 may be formed of any suitable material, such as a thermally insulating flexible polymer, and is used to prevent heat loss from the material delivery systems 104 into the surrounding environment and to protect personal from undesirable heat hazards through accidental contact with the material delivery system 104.

In some embodiments, one or more of the material delivery systems 104 operate under vacuum conditions to deliver the vapor-phase organic material into the processing volume 118 without the use of a carrier or push gas. In those embodiments, a delivery line valve 150 disposed on a delivery line 146 between the vapor source 142 and the lid plate 114 is opened and the vapor-phase organic material is allowed to flow therethrough. Here, the delivery line valves 150 are shut-off valves configured to start and stop the flow of vapor-phase deposition material therethrough and, when desired, to fluidly isolate the processing volume 118 from the vapor sources 142. Typically, the delivery line valves 150 are heated using one of the heaters 148, dedicated heaters (not shown), or a combination thereof, to maintain the delivery line valves 150 at desired temperatures and thus prevent condensation of vapor-phase organic material on the inner surfaces thereof.

When operating under vacuum conditions, the flowrates of the vapor-phase organic materials are at least partially controlled by maintaining a pressure differential between the processing volume 118 and the vapor sources 142. The pressure differential may be maintained by using the valve 120 fluidly coupled to the processing volume, adjusting the temperature of the vapor source 142 and thus the pressure of the vapor-phase organic material disposed therein, or both.

Operating the material delivery systems 104 under vacuum conditions beneficially reduces film contamination or quality risks associated with the use of a carrier gas. Unfortunately, in the above described embodiments residual vapor phase organic material disposed in the delivery lines 146 and the showerheads 136 will continue to bleed into the processing volume 118 after the delivery line valves 150 are closed. Thus, stopping the flow of vapor phase organic material into the processing volume 118 when the material delivery systems are operating under vacuum conditions, without the use of a carrier gas, can take longer than desired. For example, once a delivery line valve 150 is closed (or substantially closed) residual vapor-phase organic material disposed in a delivery line 146 and in a showerhead 136 may be continuously drawn into the processing volume 118. Undesired flow of residual vapor-phase organic material into the processing volume 118 may complicate substrate handling and result in undesired deposition on surfaces therein. Examples of undesired material deposition include condensation of the vapor-phase organic material on the substrate support 122 and on trailing and leading edges of the substrate 124, substrate carrier 126, and shadow mask assembly 128 respectively being unloaded and loaded to and from the substrate support 122. Thus, in some embodiments, one or more of the material delivery systems 104 further comprises a processing volume bypass system which may be used to draw residual material from the showerheads 136 and the delivery lines 146 into the cold trap 121 without the residual material traveling through the processing volume 118.

Here, each bypass system includes a bypass line 152 and bypass valve 154 disposed on the bypass line 152. The bypass lines 152 are fluidly coupled to the respective delivery lines 146 at points disposed between the delivery line valves 150 and the showerheads 136. The bypass valves 154 are respectively disposed on the bypass lines 152 between the intersections of the bypass lines 152 with the delivery lines 146 and the cold trap 121.

When a bypass system is operating in an off-mode configuration, the respective delivery line valve 150 will be open and the bypass valve 154 will be closed. Thus, when a bypass system is in an off-mode configuration, vapor-phase organic material will flow from the respective vapor source 142 to a corresponding showerhead 136. Conversely, when a bypass system is in an on-mode configuration the respective delivery line valve 150 will be closed and the bypass valve 154 will be open. Generally, the pressure in the processing volume 118 is more than the negative pressure provided by the vacuum source 119 to the bypass lines 152. Thus, when a bypass system is placed into an on-mode configuration, residual vapor-phase organic material disposed in the delivery line 146 and showerhead 136 will be drawn into or towards the bypass line 152 which will stop the flow of the residual material from the showerhead 136. Use of the bypass systems advantageously allows for vapor-phase organic material flow into the processing volume 118 to be stopped quickly, thus enabling fine control over the organic vapor deposition process.

In other embodiments, the material delivery system 104 uses a carrier gas to facilitate delivery of a vapor-phase organic material from one or more of the vapor sources 142 to the processing volume 118. For example, in some embodiments each of the vapor sources 142 are fluidly coupled (shown in phantom) to a gas source 156. The gas source 156 delivers a non-reactive carrier gas, such as Ar, N₂, or He, to the desired vapor source 142 to mix with and then carry, or to push, the vapor-phase organic material into the processing volume 118. In some embodiments, the material delivery systems 104 or portions thereof, e.g., individual vapor sources 142 and delivery lines 146 fluidly coupled thereto, are purged before and after maintenance operations using a purge gas delivered from the gas source 156.

In some embodiments, at least portions of the bypass systems, such as the bypass lines 152, bypass valves 154, connections therebetween, and connections fluidly coupling the bypass lines 152 to the delivery lines 146 may be heated using a heater 148 and may be insulated using an insulating jacket 157.

In embodiments herein, operation of the processing system 100 is directed by a system controller 160. The system controller 160 includes a programmable central processing unit (CPU) 162 which is operable with a memory 164 (e.g., non-volatile memory) and support circuits 166. The support circuits 166 are conventionally coupled to the CPU 162 and comprise cache, clock circuits, input/output subsystems, power supplies, and the like, and combinations thereof coupled to the various components of the processing system 100, to facilitate control thereof. The CPU 162 is one of any form of general purpose computer processor used in an industrial setting, such as a programmable logic controller (PLC), for controlling various components and sub-processors of the processing system. The memory 164, coupled to the CPU 162, is non-transitory and is typically one or more of readily available memories such as random access memory (RAM), read only memory (ROM), floppy disk drive, hard disk, or any other form of digital storage, local or remote.

Typically, the memory 164 is in the form of a non-transitory computer-readable storage media containing instructions (e.g., non-volatile memory), which when executed by the CPU 162, facilitates the operation of the processing system 100. The instructions in the memory 164 are in the form of a program product such as a program that implements the methods of the present disclosure. The program code may conform to any one of a number of different programming languages. In one example, the disclosure may be implemented as a program product stored on computer-readable storage media for use with a computer system. The program(s) of the program product define functions of the embodiments (including the methods described herein).

Illustrative non-transitory computer-readable storage media include, but are not limited to: (i) non-writable storage media (e.g., read-only memory devices within a computer such as CD-ROM disks readable by a CD-ROM drive, flash memory, ROM chips or any type of solid-state non-volatile semiconductor memory devices, e.g., solid state drives (SSD)) on which information may be permanently stored; and (ii) writable storage media (e.g., floppy disks within a diskette drive or hard-disk drive or any type of solid-state random-access semiconductor memory) on which alterable information is stored. Such computer-readable storage media, when carrying computer-readable instructions that direct the functions of the methods described herein, are embodiments of the present disclosure. In some embodiments, the methods set forth herein, or portions thereof, are performed by one or more application specific integrated circuits (ASICs), field-programmable gate arrays (FPGAs), or other types of hardware implementations. In some other embodiments, the substrate processing methods set forth herein are performed by a combination of software routines, ASIC(s), FPGAs and, or, other types of hardware implementations.

FIGS. 2A-2D schematically illustrate aspects of an integrated lid assembly 200 having at least portions of material delivery systems 206 disposed thereon, according to one embodiment. FIG. 2A is a bottom isometric view of the integrated lid assembly 200 (not showing the material delivery systems 206). FIG. 2B is a right-side-up sectional view of the lid assembly 200 taken along line A-A of FIG. 2A and further showing the integrated material delivery systems 206. FIG. 2C is a close-up sectional view of a portion of an integrated material delivery system 206 shown in FIG. 2B. FIG. 2D is a close-up sectional view of another portion of an integrated material delivery system 206 shown in FIG. 2B. The integrated lid assembly 200, or portions thereof in any combination, may be used with the processing system 100 described in FIG. 1 in place of the lid assembly 112 and material delivery systems 104.

Here, the integrated lid assembly 200 includes a lid plate 202, a showerhead assembly 204, and a plurality of material delivery systems 206 (shown in FIG. 2B). A processing volume facing surface of the lid plate 202 features a sidewall mating surface 208, a sealing ring channel 210, and a recessed surface 212. The sidewall mating surface 208 comprises an annular indention. The sealing ring channel 210 is formed within the boundaries defined by the sidewall mating surface 208. The recessed surface 212 is disposed radially inward of the sidewall mating surface 208. Typically, the lid assembly 200 is vacuum sealed to one or more sidewalls of a processing chamber using a sealing ring 211 (shown in FIG. 2B) disposed in the sealing ring channel 210. Here, the lid plate 202 further includes one or more cooling conduits 209 (shown in FIG. 2B) disposed therein which when coupled to a coolant source (not shown), such as a refrigerant source or water source, may be used to maintain the lid plate 202 at or below a desired temperature.

The showerhead assembly 204 features a plurality of showerheads 214 (four shown). Here, each of the showerheads 214 have a generally cylindrical sector shape, (i.e., pie-slice-shape) which collectively form a generally cylindrically shaped showerhead assembly 204. Each of the showerheads 214 includes a backing plate 215 (FIG. 2B), a faceplate 226 having a plurality of openings 228 disposed therethrough, and a peripheral wall 230 joining the backing plate 215 to the faceplate 226 to collectively define a cavity 232 (FIG. 2B). During substrate processing, vapor-phase organic materials are delivered from the vapor sources 242 to the cavities 232 and are distributed into a processing volume of a processing chamber, such as the processing chamber 102 of FIG. 1, through the plurality of openings 228.

Typically, the temperature of each of the showerheads 214 is controlled independently from the temperatures of each of the other showerheads 214 using a respective heater 216 (FIG. 2B) disposed in, on, or otherwise in thermal communication therewith. Here, the showerheads 214 are spaced apart from one another by a gap 222 having a width X(1) of about 1 mm or more, such as about 5 mm or more, or about 10 mm or more, to prevent or substantially reduce heat transfer, and thus thermal cross-talk, therebetween. In some embodiments, the showerhead assembly 204 further includes reflectors, such as the reflectors 141 shown in FIG. 1, that surround each of the showerheads 214 to prevent heat loss therefrom and to prevent thermal cross-talk therebetween.

The showerhead assembly 204 further includes a plurality of first mounts 223 coupled to, or formed from, the radially outwardly facing surfaces of the peripheral walls 230. The plurality of first mounts 223 are mated with corresponding ones of a plurality of second mounts 224 coupled to the lid plate and are secured thereto with respective fasteners 218. The center of the showerhead assembly 204, here the radially inward-most surfaces of each of the showerheads 214, is supported by a center pin 225 which is coupled to the lid plate 202 and extends downward therefrom. Here, the plurality of second mounts 224 extend outwardly from the recessed surface 212 to cause the showerheads 214 to be spaced apart from, and thus thermally isolated from, the lid plate 202 by a distance X(2) of about 5 mm or more, such as about 10 mm or more. In some embodiments, one or both of the plurality of second mounts 224 and the center pin 225 are formed of a thermally insulating material to prevent or substantially reduce thermal communication between the showerheads 214 and the lid plate 202.

Each of the material delivery systems 206 (two of four are shown) includes a vapor source 242, a delivery line 246, a delivery line valve 250, a bypass line 252, and a bypass valve 254. The delivery line valves 250 and the bypass valves 254 are operated using actuators 256, 258 respectively coupled thereto. Here, the delivery lines 246 fluidly couple each of the vapor sources 242 to a showerhead 214 in a one-to-one relationship where each individual showerhead 214 has an individual vapor source 242 corresponding thereto. In other embodiments, one or more of the material delivery systems 206 are configured to deliver vapor-phase organic material from one individual vapor source 242 to a plurality of showerheads 214, such as two or more showerheads 214, using a second delivery line, such as one of the second delivery lines 147 described in FIG. 1.

The delivery line valves 250 are respectively disposed on the delivery lines 246 at points between the showerheads 214 and the vapor sources 242. The bypass lines 252 are fluidly coupled to the respective delivery lines 246 at points disposed between the delivery line valves 250 and the showerheads 214. The bypass valves 250 are disposed on the bypass lines 252 at points between the respective intersections of the bypass lines 252 with the delivery lines 246 and a vacuum source or cold trap, such as the vacuum source 119 or cold trap 121 described in FIG. 1.

In some embodiments, the material delivery system 206 does not use a carrier gas, e.g., a pressurized “push” gas, to facilitate delivery of vapor-phase organic material from the vapor sources 242 to the showerheads 214. Instead the vapor-phase organic materials are drawn from the vapor sources 242 through the delivery lines 246 to a processing volume by a pressure differential maintained therebetween, such as described above in FIG. 1. In other embodiments, one or more of the material delivery systems 206 are coupled to a gas source, such as the gas source 156 described in FIG. 1, which provides carrier gases or purge gases thereunto.

In some embodiments, one or both of the delivery line valves 250 and the bypass valves 254 are shut-off valves having a dual action design comprising a “soft” or “hard” sealing action. When using the soft sealing action, the flow of vapor-phase organic material through a delivery line valve 250 will be substantially restricted, e.g., the cross sectional flow area will be reduced by more than about 95%, such as more than about 99%, but less than 100%. When using the hard sealing action, the flow of vapor-phase organic material through a delivery line valve 250 will be completely restricted to fluidly isolate a showerhead 214 from a respective vapor source 242. Typically, the soft sealing action is used during and between substrate processing operations to at least substantially close a delivery line valve 244, and thus substantially stop the delivery of vapor-phase organic materials from a vapor source 242 into a processing volume. The hard sealing action is typically used to completely close a delivery line valve 250 during maintenance operations when the material delivery system 206, and thus the delivery line valve 250 has been allowed to cool. For example, the hard sealing action may be used to prevent contamination of a processing volume when the vapor source 242 is opened to atmospheric conditions for reloading with organic material. Likewise, the hard sealing action may be used to prevent atmospheric contamination of a vapor source 242 when a processing chamber fluidly coupled thereto is opened for maintenance operations. The ability to use a soft sealing action beneficially reduces damage to a valve that might otherwise be incurred if the valve was completely seated at the relatively high operating temperatures described herein. Thus, the dual action valve design provides a longer useful lifetime when compared to a conventional single sealing action shut-off valve.

Herein, at least portions of the material delivery systems 206 are disposed on or above the lid plate to reduce the overall cleanroom footprint (horizontal space occupied by a system in a clean room) which would otherwise be occupied by the processing system 100 described FIG. 1. For example, in some embodiments one or more of the vapor sources 242, the delivery lines 246, the valves 250, 254 and respective actuators 256, 258 coupled thereto, and at least portions of the bypass lines 252 are disposed in a region above the lid plate 202 when the lid assembly 200 is disposed on the walls of a processing chamber.

In some embodiments, one or both of the actuators 256, 258 are coupled to, disposed on, or otherwise supported by the lid plate 202 to respectively hold the valves 250, 254, the delivery lines 246, and the bypass lines 252 in a spaced apart relationship from the lid plate 202 and thus thermally isolated therefrom. In some embodiments, portions of the material delivery systems 206 including one or more of the vapor sources 242, the delivery lines 246, the valves 250, 254 and respective actuators 256, 258 coupled thereto, and at least portions of the bypass lines 252 are enclosed in a protective housing 259 (shown in phantom) which is coupled to the lid plate 202 and disposed there over. Beneficially, the integrated lid assembly 200 allows access into to a processing volume of a processing chamber without disconnecting the vapor sources 242 or delivery lines 246 which simplifies maintenance and cleaning thereof. In some embodiments, the bypass lines 252 may still need to be disconnected from the cold trap or vacuum source before the integrated lid assembly 200 may be moved away from a processing chamber. Further, by locating the vapor sources 242 and other components of the material delivery systems 206 closer to the processing chamber the length of the delivery lines 246 between the delivery lines valves 250 and the showerheads 236 may be shortened. Shortening the length of the portions of the delivery lines 246 disposed between the valves 250 and the showerheads 236 beneficially reduces waste of expensive organic deposition materials which would otherwise be diverted to exhaust when a bypass system is in an on-mode configuration.

FIG. 2C is a close-up view of a portion of FIG. 2B which features a sectional view of a vapor source 242 and a portion of a delivery line 246. Here, the vapor source 242 is an ampoule comprising a container 260 having solid-phase organic material 262, e.g., and organic powder, disposed therein. The container 260 is sealingly coupled to a housing 264 which is fluidly coupled to the delivery line 246 through an outlet disposed through an upper region of the housing 264. Typically, the vapor source 242 includes a plurality of heaters 266 disposed around and below the container 260 which are used to form independently controlled heating zones 268a-f. In some embodiments, the independently controlled heating zones 268a-f are used to provide thermal uniformity to the vapor source 242 as the amount of the solid-phase organic material 262 disposed in the vapor source 242 is depleted over time.

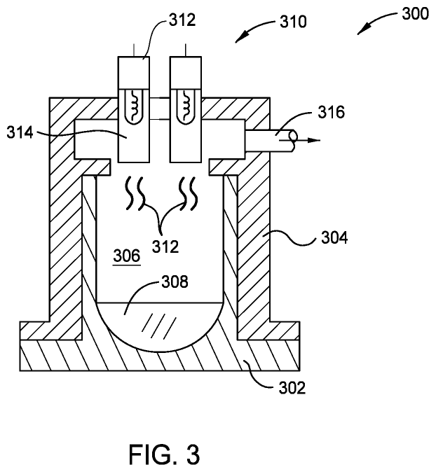

In some embodiments, the heating zones 268a-f are used to vary the temperature of the vapor source 242, and thus vary the temperature of the organic material disposed therein, from the lower portion of the ampoule to the upper portion. For example the heating zones 268a-f may be used to maintain the solid phase deposition material 262 disposed towards a base of the container 260 at a first temperature while heating the sublimated vapor-phase organic material disposed towards the top of the container 260 to a second temperature which is greater than the first temperature. An alternative embodiment to the vapor source 242 which may be used with the integrated lid assembly 200 or with the processing system 100 is further shown and described in FIG. 3.

FIG. 2D is a close-up sectional view of a portion of the FIG. 2B which features a portion of a delivery line 246 sealingly extending through an opening 238 disposed through the lid plate 202. Here, the delivery line 246 comprises a first conduit 246a fluidly coupled to a vapor source 242 and a second conduit 246b fluidly coupling the first conduit 246b to a showerhead 214. Here, the first and second conduits 246 a, b are coupled using a slip fit type connection 270 which is disposed below an upper surface of the bellows 240. As shown, the first and second conduits 246a, b are heated along the combined lengths thereof from the vapor source 242 to the showerhead 214 by a heater 248, such as a resistive heating element, which may be disposed in an insulating jacket 257. In some embodiments, the second conduit 246b is not heated. In some embodiments, one or both of a portion of the first conduit 246a disposed in the region below the bellows 240 and the second conduit 246b is not heated. In some embodiments, one or both of a portion of a first conduit 246a disposed in the region below the bellows 240 and the second conduit 246b are heated using a heater which is independent of the heater 248 used to heat the portion of the delivery line 246 disposed between the bellows 240 and the vapor source 242.

In some embodiments, each material delivery system 206 features a plurality of independently controlled heaters 248 which may be used to form a multi-zone control heating system similar or the same as the multi-zone control heating system 149 shown and described in FIG. 1.

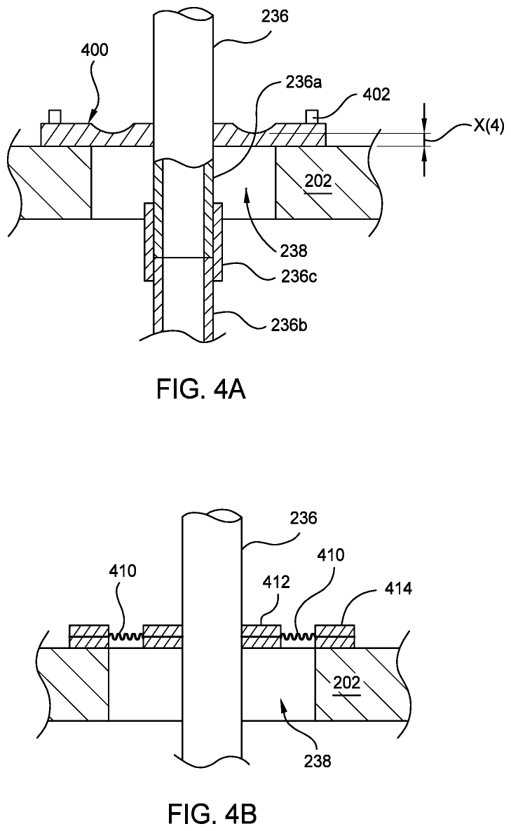

Herein, the openings 238 in the lid plate 202 are sized to prevent direct contact between the lid plate 202 and the delivery lines 246. For example, in one embodiment the delivery lines 246 are spaced apart from the walls of the respective openings 238 by a distance X(3) of about 1 mm or more, such as about 3 mm or more, 5 mm or more, 7 mm or more, 9 mm or more, or for example about 10 mm or more to limit thermal communication there between. Limiting thermal communication between the lid plate 202 and the delivery lines 246 desirably prevents cold spots from forming in the corresponding portions of the delivery lines 246 and undesirable condensation of the vapor-phase organic material on the walls thereof is thus avoided. Alternative embodiments for coupling the first and second conduits 246a, b and sealing a processing volume when the lid assembly 200 is disposed thereon are shown in FIGS. 4A-4B.

FIG. 3 is a close up sectional view of a vapor source 300, according to another embodiment, which may be used in place of one or more of the vapor sources 142, 242 respectively described in FIGS. 1 and 2A. Here, the vapor source 300 features a container 302 having a solid-phase organic material 308 disposed therein. The container 302 is sealingly coupled to a housing 306 which may be coupled to a heated delivery line of one of the material delivery systems described herein. The vapor source 300 features a lamp assembly 310 comprising a plurality of lamps 312 each disposed in a corresponding light pipe 314 so that radiant thermal energy 316 emitted by the lamps 312 is directed towards the solid-phase organic material 304 disposed there below. The radiant thermal energy 316 is used to sublimate the organic material 304 into a vapor-phase thereof which is then flowed from the vapor source 300 through an outlet 318 to a delivery line (not shown) fluidly coupled thereto. In some embodiments, the vapor source 300 is fluidly coupled to a carrier gas source, such as the gas source 156 described in FIG. 1 which mixes with and carries or pushes the vapor phase organic material through the delivery lines to a showerhead fluidly coupled thereto.

In some embodiments, one or more features of the vapor source 300 may be combined with one or more features of the vapor source 242. For example, in some embodiments the vapor source 300 further includes a plurality of heaters, such as the heaters 266 disposed around and/or below the container 302. The heaters may be independently operable to provide a multi-zone heater comprising a plurality of heating zones, such as the heating zones 268a-f set forth in FIG. 2. In those embodiments, the heaters 266 may be used to maintain the organic material 262 at a temperature at or near the sublimation point thereof and the lamps 312 may be used to flash sublimate organic material from the surface only when vapor-phase organic material flow from the vapor source 300 is desired.

FIGS. 4A and 4B are schematic sectional views illustrating alternative embodiments to the bellows described above in FIGS. 2B and 2D. In FIG. 4A the delivery line 246 is sealingly disposed through the lid plate 202 using an annular metal flange 400 circumferentially disposed about the delivery line 246 to couple the delivery line 246 to the lid plate 202. Here, the flange 400 has a thickness X(4) of less than about 10 mm between the outer and inner diameter thereof to reduce the cross-sectional area available for heat transfer between the delivery line 246 and the lid plate 202 and thus limit thermal communication there between. In some embodiments the thickness X(4) is less than about 8 mm, such as less than about 6 mm, less than about 4 mm, for example less than about 2 mm. Here, the first conduit 246a and the second conduit 246b are fluidly coupled by an external coupler 246c disposed over the respective ends thereof. Heaters (not shown) may be coupled to one or more of the conduits 246a-c in one or any combination of the embodiments described in FIGS. 1 and 2A-2D above.

In FIG. 4D a delivery line 246 is sealingly coupled to a lid plate 202 using a flexible gasket 410, such as a silicone gasket, which is coupled to and clamped between the delivery line 246 and the lid plate 202. Here, the delivery line 246 comprises one or any combination of the embodiments described above in FIGS. 1, 2A-2D, and FIG. 4A above.

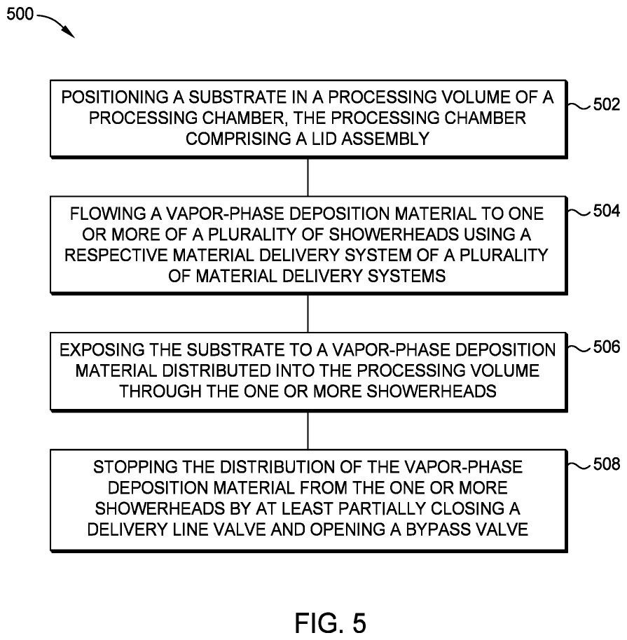

FIG. 5 is a flow diagram setting forth a method 500 of processing a substrate using any one or combination of embodiments of the organic vapor deposition systems described herein.

At activity 502 the method 500 includes positioning a substrate in a processing volume of a processing chamber. Typically, the substrate is one which is suitable for semiconductor device manufacturing, e.g., a silicon wafer, and has a plurality of semiconductor devices formed thereon. In some embodiments, the substrate comprises a plurality of semiconductor devices each comprising a plurality of complementary metal-oxide semiconductor (CMOS) transistors. In some embodiments, the substrate comprises a first electrode layer, such as a first indium tin oxide layer (ITO) disposed on the plurality of CMOS devices. In some embodiments, the substrate is disposed on a substrate carrier which is used to transport the substrate along with a shadow mask assembly disposed thereon, such as described above in FIG. 1. Here, the processing chamber comprises the integrated lid assembly or alternative embodiments thereof as shown and described above in one or any combination of the embodiments set forth in FIGS. 1, 2A-2D, 3, and 4A-4B.

At activity 504 the method 500 includes flowing a vapor-phase organic material to one or more of a plurality of showerheads using a respective material delivery system of a plurality of material delivery systems. Examples of suitable organic materials which may be used to form an organic photo-detector using the method 500 include Tris(8-hydroxyquinolinato), aluminum (Alq3), and Buckminsterfullerene (C₆₀). Typically, sublimating and maintaining the organic materials in a vapor-phase using the material delivery systems described herein requires heating the components of the material delivery systems to temperatures up to, and in some embodiments above, 600 degrees Celsius.

At activity 506 the method 500 includes exposing the substrate to one or more vapor-phase organic materials which have been distributed into the processing volume through the one or more showerheads. In some embodiments, two or more organic materials are flowed from respective vapor sources in to the processing volume either concurrently or consecutively. For example, in some embodiments a first organic material is flowed from one or more showerheads and a second organic material, which is different from the first organic material, is concurrently flowed from one or more of the remaining showerheads which are not being used for the first organic material. The substrate support is rotated while the first and second organic materials are co-flowed into the processing volume to control intermixing of the organic materials as they are condensed onto a device side surface of the substrate. Typically, slower rotation of the substrate results in less intermixing of the different organic materials to provide a laminated multi-layer structure while faster rotation provides a greater degree of intermixing and thus a more homogenous distribution of the two or more organic materials.

At activity 508 the method 500 includes stopping the distribution of the vapor-phase deposition material from the one or more showerheads by at least partially closing a delivery line valve and opening a bypass valve such as described above in one or any combination of the embodiments of FIGS. 1, 2A-2D, 3, and 4A-4B.

Beneficially, embodiments described herein allow for the integration of organic vapor deposition processes into a high volume semiconductor device manufacturing line.

While the foregoing is directed to embodiments of the present disclosure, other and further embodiments of the disclosure may be devised without departing from the basic scope thereof, and the scope thereof is determined by the claims that follow.

1. A processing system, comprising:
a lid assembly, comprising:
a lid plate having a first surface and a second surface disposed opposite of the first surface; and
a showerhead assembly coupled to the first surface, the showerhead assembly comprising a plurality of showerheads; and
a plurality of material delivery systems disposed on the second surface of the lid plate, wherein individual ones of the plurality of material delivery systems are fluidly coupled to one or more of the plurality of showerheads, and the individual ones of the material delivery systems each comprise:
a delivery line;
a delivery line valve disposed on the delivery line;
a bypass line fluidly coupled to the delivery line at a point disposed between the delivery line valve and the showerhead; and
a bypass valve disposed on the bypass line.

2. The processing system of claim 1, wherein the individual showerheads are fluidly coupled to individual vapor sources in a one-to-one relationship.

3. The processing system of claim 1, wherein the individual ones of the material delivery systems each further comprise a vapor source comprising a plurality of lamps each disposed in a corresponding light pipe.

4. The processing system of claim 1, wherein
the delivery lines are disposed through corresponding openings formed in the lid plate, and
the openings in the lid plate and the delivery lines are respectively sized to prevent contact there between.

5. The processing system of claim 1, further comprising a non-transitory computer readable medium having instructions stored thereon for performing a method of processing a substrate when executed by a processor, the method comprising:
positioning a substrate in a processing volume of a processing chamber, the processing chamber comprising the lid assembly;
rotating the substrate;
flowing a vapor-phase deposition material to one or more of the plurality of showerheads using a respective material delivery system of the plurality of material delivery systems;
exposing the rotating substrate to one or more vapor-phase organic materials distributed into the processing volume through the one or more of the plurality of showerheads; and
stopping the flow of the vapor-phase organic materials from the one or more showerheads comprising:
at least partially closing the delivery line valve; and
opening the bypass valve.

6. The processing system of claim 5, wherein each of the plurality of showerheads are independently heated using a corresponding heater disposed in thermal communication therewith, and wherein each of the plurality of showerheads are spaced apart from adjacently disposed showerheads by a gap of about 1 mm or more.

7. The processing system of claim 5, wherein one or more of the plurality of material delivery systems comprises a plurality of independently controlled heaters each in thermal communication with a portion of the delivery line to provide a corresponding plurality of independently controlled heating zones between a vapor-phase precursor source of the material delivery system and a corresponding shower head in fluid communication therewith.

8. The processing system of claim 1, wherein the bypass lines fluidly couple the delivery lines to a vacuum source.

9. A non-transitory computer readable medium having instructions stored thereon for performing a method of processing a substrate when executed by a processor, the method comprising:
positioning a substrate in a processing volume of a processing system, the processing system comprising a lid assembly;
flowing a vapor-phase deposition material to one or more of a plurality of showerheads using a respective material delivery system of a plurality of material delivery systems;
exposing the substrate to one or more vapor-phase organic materials which have been distributed into the processing volume through the one or more of the plurality of showerheads; and
stopping the flow of the one or more vapor-phase organic materials from the one or more showerheads, comprising:
at least partially closing a delivery line valve; and
opening a bypass valve.

10. The non-transitory computer readable medium of claim 9, wherein the processing system comprises:
the lid assembly, comprising:
a lid plate having a first surface and a second surface disposed opposite of the first surface; and
a showerhead assembly coupled to the first surface, the showerhead assembly comprising the plurality of showerheads; and
a plurality of material delivery systems disposed on the second surface of the lid plate, wherein individual ones of the plurality of material delivery systems are fluidly coupled to one or more of the plurality of showerheads, and an individual one of the material delivery systems comprises:
a delivery line;
the delivery line valve disposed on the delivery line;
a bypass line fluidly coupled to the delivery line at a point disposed between the delivery line valve and the showerhead; and
the bypass valve disposed on the bypass line.

11. The non-transitory computer readable medium of claim 10, wherein the individual showerheads are fluidly coupled to individual vapor sources in a one-to-one relationship.

12. The non-transitory computer readable medium of claim 10, wherein the individual ones of the material delivery systems each further comprise a vapor source, wherein the vapor source comprises a plurality of lamps each disposed in a corresponding light pipe, and wherein the method further includes directing radiant energy from the lamps to vaporize deposition material disposed in the vapor source.

13. The non-transitory computer readable medium of claim 10, wherein
the delivery lines are disposed through corresponding openings formed in the lid plate, and
the openings in the lid plate and the delivery lines are respectively sized to prevent contact there between.

14. The non-transitory computer readable medium of claim 10, wherein each of the plurality of showerheads are independently heated using a corresponding heater disposed in thermal communication therewith, and wherein each of the plurality of showerheads are spaced apart from adjacently disposed showerheads by a gap of about 1 mm or more.

15. The non-transitory computer readable medium of claim 10, wherein one or more of the plurality of material delivery systems comprises a plurality of independently controlled heaters each in thermal communication with a portion of the delivery line to provide a corresponding plurality of independently controlled heating zones between a vapor-phase precursor source of the material delivery system and a corresponding showerhead in fluid communication therewith.

16. The non-transitory computer readable medium of claim 10, wherein the bypass lines fluidly couple the delivery lines to a vacuum source.

17. A method of processing a substrate, comprising:
positioning a substrate in a processing volume of a processing system, the processing system comprising a lid assembly;
flowing a vapor-phase organic material to one or more of a plurality of showerheads using a respective material delivery system of a plurality of material delivery systems;
exposing the substrate to one or more vapor-phase organic materials which have been distributed into the processing volume through the one or more showerheads; and
stopping the flow of the one or more vapor-phase organic materials from the one or more showerheads comprising:
at least partially closing a delivery line valve; and
opening a bypass valve.

18. The method of claim 17, wherein the processing system comprises:
the lid assembly, comprising:
a lid plate having a first surface and a second surface disposed opposite of the first surface; and
a showerhead assembly coupled to the first surface, the showerhead assembly comprising the plurality of showerheads; and
a plurality of material delivery systems disposed on the second surface of the lid plate, wherein individual ones of the plurality of material delivery systems are fluidly coupled to one or more of the plurality of showerheads, and an individual one of the material delivery systems comprises:
a delivery line;
the delivery line valve disposed on the delivery line;
a bypass line fluidly coupled to the delivery line at a point disposed between the delivery line valve and the showerhead; and
the bypass valve disposed on the bypass line.

19. The method of claim 18, wherein
the delivery lines are disposed through corresponding openings formed in the lid plate, and
the openings in the lid plate and the delivery lines are respectively sized to prevent contact there between.

20. The method of claim 18, wherein the individual ones of the material delivery systems each further comprise a vapor source, wherein the vapor source comprises a plurality of lamps each disposed in a corresponding light pipe, and wherein the method further includes directing radiant energy from the lamps to vaporize deposition material disposed in the vapor source.
